(19) United States
(12) Patent Application Publication
(10) Pub. No.: US 2025/0149596 A1
(43) Pub. Date: May 8, 2025

(54) ENERGY STORAGE DEVICE AND METHOD OF MANUFACTURING CURRENT COLLECTOR THEREOF

(71) Applicants: Industrial Technology Research Institute, Hsinchu (TW); National Tsing Hua University, Hsinchu City (TW)

(72) Inventors: Hung-Hsin Shih, Hsinchu City (TW); Kun-Ping Huang, Miaoli County (TW); Chi-Chang Hu, Hsinchu City (TW); Hao-Yu Ku, Hsinchu City (TW)

(73) Assignees: Industrial Technology Research Institute, Hsinchu (TW); National Tsing Hua University, Hsinchu City (TW)

(21) Appl. No.: 18/537,808

(22) Filed: Dec. 13, 2023

(30) Foreign Application Priority Data
Nov. 8, 2023 (TW) 112142984

(51) Int. Cl. H01M 4/66; C23C 16/26; H01M 10/052; H01M 10/0568; H01M 10/0569

(52) U.S. Cl. CPC H01M 4/663; C23C 16/26; H01M 10/052; H01M 10/0568; H01M 10/0569

(57) ABSTRACT

A method of manufacturing a current collector of an energy storage device includes the following. A substrate is provided. A modified layer is formed on the substrate using a microwave plasma chemical vapor deposition process. The modified layer includes nanographene and has a thickness of 1 nm to 500 nm. In the microwave plasma chemical vapor deposition process, a microwave frequency is 300 MHz to 300 GHz, a microwave power is 500 W to 75000 W, a temperature is 25° C. to 600° C., and a deposition time is less than 30 minutes. The microwave plasma chemical vapor deposition process includes the following. Inert gas or stable gas is passed in. Hydrocarbon gas and hydrogen are passed in. Microwaves are applied to generate plasma. The hydrocarbon gas and the hydrogen are ionized. Nanographene is formed on the substrate.

### CROSS-REFERENCE TO RELATED APPLICATION

This application claims the priority benefit of Taiwan patent application no. 112142984, filed on Nov. 8, 2023. The entirety of the above-mentioned patent application is hereby incorporated by reference herein and made a part of this specification.

### TECHNICAL FIELD

The technical field relates to an energy storage device and a method of manufacturing a current collector thereof.

### BACKGROUND

In the development of electrodes of anode-free lithium batteries, copper foil is often used as a Cu current collector for lithium metal plating. However, during reduction of lithium ions (or during charging), lithium metal dendrites (or lithium dendrites) are likely to form and break through a separator, thus causing problems such as a short circuit or a fire in the batteries and reduction of battery life.

Although the formation of lithium metal dendrites during reduction of lithium ions can be prevented by modifying a surface of copper foil, most of the current methods of modifying the surface of copper foil are complex and time-consuming.

### SUMMARY

One of exemplary embodiments comprises a method of manufacturing a current collector of an energy storage device. The method includes the following. A substrate is provided. A modified layer is formed on the substrate using a microwave plasma chemical vapor deposition process. The modified layer includes nanographene and has a thickness of 1 nanometer (nm) to 500 nm. In the microwave plasma chemical vapor deposition process, a microwave frequency is megahertz (MHz) to 300 gigahertz (GHz), a microwave power is 500 watts (W) to 75000 W, a temperature is 25° C. to 600° C., and a deposition time is less than 30 minutes. The microwave plasma chemical vapor deposition process includes the following. Inert gas or stable gas is passed in. Hydrocarbon gas and hydrogen are passed in. Microwaves are applied to generate plasma. The hydrocarbon gas and the hydrogen are ionized using the plasma. Nanographene is formed on the substrate.

Several exemplary embodiments accompanied with figures are described in detail below to further describe the disclosure in details.

### BRIEF DESCRIPTION OF DRAWINGS

FIG. 1 is a schematic structural diagram of an energy storage device according to an exemplary embodiment.

FIG. 2A and FIG. 2B are images of nanographene on a current collector as observed using a scanning electron microscope.

FIG. 2C shows a Raman spectrum of nanographene on the current collector as measured using a Raman spectrometer.

FIG. 3A to FIG. 3C are top views of lithium metal on the current collector as observed using a scanning electron microscope.

FIG. 3D to FIG. 3F are side views of lithium metal on the current collector as observed using a scanning electron microscope.

FIG. 4 and FIG. 5 respectively show relationships between Coulombic efficiency and cycle number of different energy storage devices.

### DETAILED DESCRIPTION

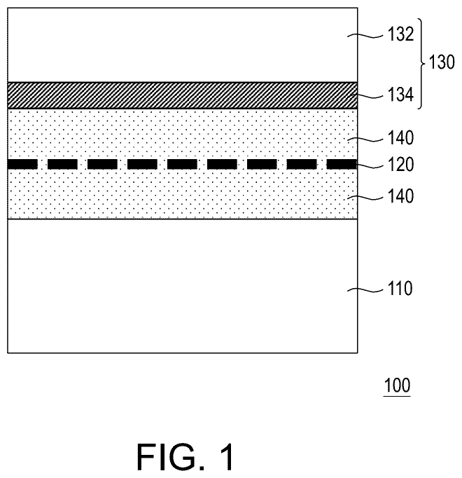

FIG. 1 is a schematic structural diagram of an energy storage device according to an exemplary embodiment.

Referring to FIG. 1, an energy storage device 100 of the present embodiment includes a cathode 110, a separator 120, a current collector 130, and an electrolytic solution 140. The energy storage device 100 may be, but is not limited to, an anode-free lithium metal battery without an anode active material.

Specifically, a material of the cathode 110 (that is, positive electrode) may include, but not limited to, lithium iron phosphate (LFP or LiFePO₄), lithium nickel manganese cobalt oxide (NMC or LiNiMnCoO₂), lithium cobalt oxide (LCO or LiCoO₂), lithium nickel cobalt aluminum oxide (NCA or LiNiCoAlO₂), or lithium foil.

The separator 120 is disposed on the cathode 110. A material of the separator 120 may include, but not limited to, polypropylene (PP) or polyethylene (PE).

The current collector 130 is disposed on the separator 120. The current collector 130 and the cathode 110 are respectively located on opposite sides of the separator 120. The current collector 130 may be, but is not limited to, an anode current collector (or a negative electrode current collector) that collects lithium metal and includes no active material.

The current collector 130 may include a substrate 132 and a modified layer 134. In the present embodiment, the substrate 132 may be of a size of, but not limited to, G2 (370 mm×470 mm) to G10 (2880 mm×3130 mm). A material of the substrate 132 may include, but not limited to, a metal material, a conductive material, or a conductive polymer material. Examples of the metal material include, but not limited to, copper, gold, silver, titanium, nickel, tin, platinum, palladium, or aluminum. Examples of the conductive polymer material include, but not limited to, polyaniline (PANI), polyacetylene (PA), polyphenyl vinylene (PPV), poly-p-phenylene (PPP), polypyrrole (PPy), or polythiophenes (PTs).

The modified layer 134 is disposed on the substrate 132, and the modified layer 134 is disposed between the substrate 132 and the separator 120. In the present embodiment, the modified layer 134 includes nanographene. The nanographene may include, for example but not limited to, 1 to 10 layers. The nanographene may be a vertically oriented graphene nanowall (GNW) or horizontal graphene. In the present embodiment, the modified layer 134 may have a thickness of, for example but not limited to, 1 nm to 500 nm or 1 nm to 100 nm.

In the present embodiment, by disposing the modified layer 134 that contains nanographene on the substrate 132, the formation of lithium dendrites on the current collector 130 during reduction of lithium ions (or during charging) can be prevented, and the safety and service life of the energy storage device 100 can be improved. Since nanographene has a more-spaced structure, energy density of the current collector 130 can be increased, thereby increasing energy density of the energy storage device 100.

The electrolytic solution 140 is disposed between the cathode 110 and the current collector 130 to provide a conductive function inside the energy storage device 100. The electrolytic solution 140 may include an electrolyte and a solvent. In the present embodiment, examples of the electrolyte include, but not limited to, lithium carbonate (Li₂CO₃), lithium hexafluorophosphate (LiPF₆), lithium tetrafluoroborate (LiBF₄), lithium bis(trifluoromethanesulfonyl)imide (LiTFSI), lithium bis(fluorosulfonyl)imide (LiFSI), or lithium nitrate (LiNO₃). Examples of the solvent include, but not limited to, ethylene carbonate (EC), dimethyl carbonate (DMC), ethyl methyl carbonate (EMC), dimethoxyethane (DME), or 1,3-dioxolane (DOL).

The following describes a method of manufacturing the current collector 130 of the energy storage device 100 of the present embodiment. The method may include, but not limited to, the following. First, the substrate 132 is provided. Next, the modified layer 134 is directly and quickly formed on the substrate 132 in a low temperature environment using a microwave plasma chemical vapor deposition (MPCVD) process.

Specifically, in the present embodiment, the microwave plasma chemical vapor deposition process may include, but not limited to, an electron cyclotron resonance chemical vapor deposition (ECR CVD) process, a multi-source electron cyclotron resonance chemical vapor deposition (MECR CVD) process, a microwave plasma torch chemical vapor deposition (MPT CVD) process, or a focused microwave plasma chemical vapor deposition (FMP CVD) process.

In the present embodiment, the microwave plasma chemical vapor deposition process may include, but not limited to, the following.

First, inert gas or stable gas is passed in. Examples of the inert gas include, but not limited to, argon. Examples of the stable gas include, but not limited to, nitrogen.

Next, hydrocarbon gas and hydrogen are passed in. The hydrocarbon gas may include alkane gas, alkene gas, or acetylene gas. The hydrocarbon gas is, for example but not limited to, methane (CH₄), ethylene (C₂H₄), or acetylene (C₂H₂). In the present embodiment, a ratio between the hydrocarbon gas and the hydrogen may be 1:10 to 10:1, such as 1:2, 2:1, or 1:1, but is not limited thereto. In some embodiments, in this step, stable gas may further be passed in. Examples of the stable gas include, but not limited to, nitrogen.

Next, microwaves are applied to generate plasma. In the present embodiment, a microwave apparatus may be, but is not limited to, an electron cyclotron resonance (ECR) apparatus, a multi-source electron cyclotron resonance (MECR) apparatus, a microwave plasma torch (MPT) apparatus, or a focused microwave plasma (FMP) reactor. A microwave frequency may range from 300 megahertz (MHz) to 300 gigahertz (GHz). A microwave power may range from 500 watts (W) to 75000 W, such as 1000 W to 70000 W, 1500 W to 65000 W, 2000 W to 60000 W, 3000 W to 55000 W, 4000 W to 50000 W, 5000 W to 45000 W, 6000 W to 40000 W, 7000 W to 35000 W, 8000 W to 30000 W, 9000 W to 25000 W, or 10000 W to 20000 W. However, the disclosure is not limited thereto.

Next, the hydrocarbon gas and the hydrogen are ionized using the plasma, and graphene is produced. In the present embodiment, the hydrocarbon gas and the hydrogen may be ionized using, for example but not limited to, argon plasma generated after microwave application.

Next, nanographene is formed on the substrate 132, and the modified layer 134 is formed. In the present embodiment, an ambient temperature (or substrate temperature) during deposition may be 25° C. to 600° C., such as 300° C. to 450° C., but is not limited thereto. In the present embodiment, a deposition time may be, but is not limited to, less than 30 minutes.

In some embodiments, the microwave plasma chemical vapor deposition process may further include the following. That is, heteroatoms are doped during formation of nanographene on the substrate 132. The heteroatoms may include nitrogen, sulfur, or silicon. For example, by doping with nitrogen during formation of nanographene, nitrogen-doped nanographene can be formed on the substrate.

Compared with a conventional method of manufacturing a current collector having a modified layer which requires multiple steps (for example, coating, deposition, and annealing), long time (for example, 2 hours or more), and/or high temperature (for example, 1000° C. or higher), in the method of the present embodiment, the current collector 130 including the modified layer 134 that contains nanographene can be manufactured by a single step (microwave plasma chemical vapor deposition process) within a relatively short time (less than 30 minutes) at a relatively low temperature (300° C. to 450° C.). The manufacturing process is simplified and shortened.

Hereinafter, the method of manufacturing a current collector of an energy storage device of the above embodiment will be described in detail through experimental examples. However, the following experimental examples are not intended to be limiting.

### Experiment Example 1

### <Formation of Current Collector>

First, copper foils fabricated by two different methods were provided, namely copper foil A (electroplated copper) and copper foil B (rolled copper), and these copper foils were cleaned with hydrochloric acid. Next, by a multi-source electron cyclotron resonance chemical vapor deposition process using a multi-source electron cyclotron resonance apparatus with acetylene as a carbon source, nanographene was formed on each of the copper foil A and the copper foil B that had been cleaned with hydrochloric acid, thereby obtaining a current collector of Example 1 and a current collector of Example 2. Specifically, in the multi-source electron cyclotron resonance chemical vapor deposition process, argon gas was passed in at a flow rate of 30 standard cubic centimeters per minute (sccm), acetylene was passed in at a flow rate of 2.5 sccm, and hydrogen was passed in at a flow rate of 5 sccm. Next, microwaves were applied at a microwave power of 1100 W and a microwave frequency of 2.45 GHz to generate argon plasma. Next, acetylene and hydrogen were ionized using the argon plasma to generate graphene, in which a temperature was set to 450° C. and a deposition time was set to 6 minutes, thereby forming nanographene on the copper foils.

The copper foil A with no nanographene deposited thereon was used as a current collector of Comparative Example 1.

### <Confirmation of Nanographene on Current Collector>

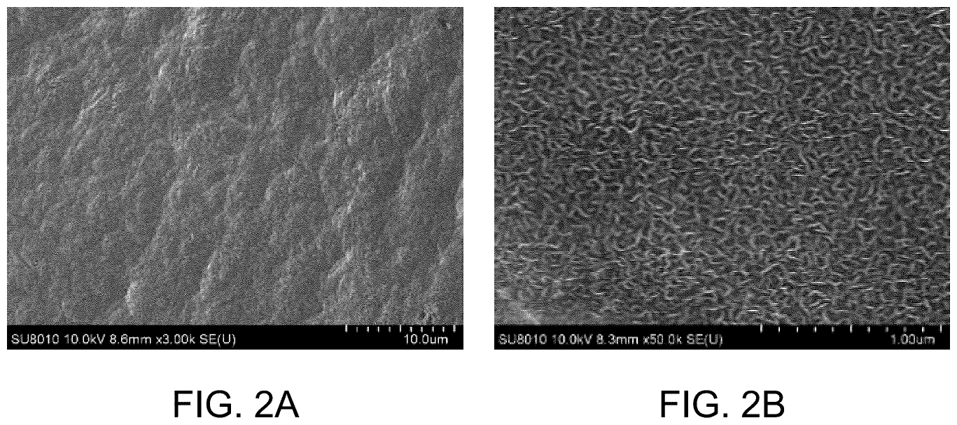

The growth of the nanographene of Example 1 and Example 2 was observed using a scanning electron microscope (SEM), and the results thereof are shown in FIG. 2A and FIG. 2B, respectively. A Raman spectrum of the nanographene of Example 1 and Example 2 was measured using a Raman spectrometer, so as to confirm whether the D peak, the G peak and the 2D peak appeared at about 1300 cm⁻¹, about 1600 cm⁻¹ and about 2600 cm⁻¹ in Raman shift in the spectrum. The results thereof are shown in FIG. 2C.

According to the results shown in FIGS. 2A and 2B, since the nanographene of Example 1 in FIG. 2A appeared smooth, it is considered that the nanographene of Example 1 was horizontal graphene. Since the nanographene of Example 2 in FIG. 2B exhibited a long vertically oriented structure, it is considered that the nanographene of Example 2 was a vertically oriented graphene nanowall.

According to the results shown in FIG. 2C, since the D peak, the G peak and the 2D peak were observed in both Example 1 and Example 2, it is evident that nanographene was present on the copper foils of Example 1 and Example 2.

### <Confirmation of Growth of Lithium Metal on Current Collector>

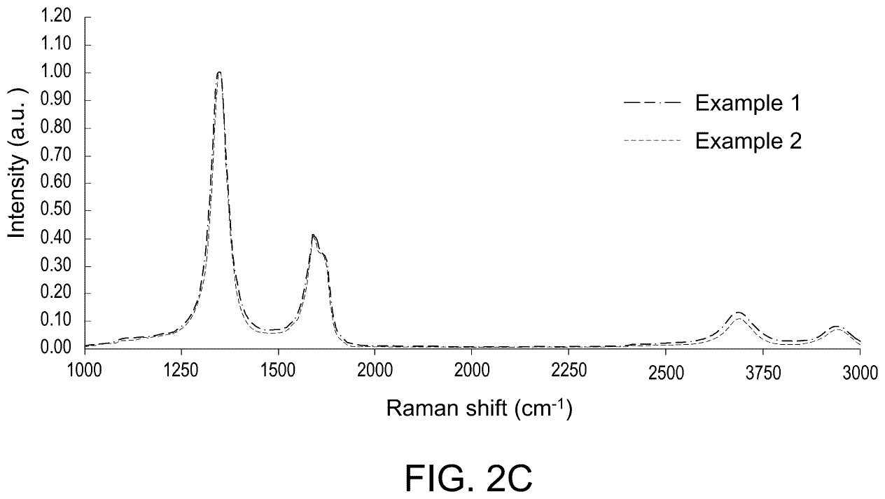

Lithium metal was deposited using 1 M of lithium bis(trifluoromethanesulfonyl)imide on each of Comparative Example 1 (that is, the copper foil A with no nanographene deposited thereon), Example 1, and Example 2. Next, the growth of the lithium metal was observed using a scanning electron microscope, and the results thereof are shown in top views in FIG. 3A to FIG. 3C and side views in FIG. 3D to FIG. 3F.

According to the results shown in FIG. 3A and FIG. 3D, the lithium metal on the current collector of Example 1 exhibited a fluffy spherical structure or a fine needle-like uniform lump structure, which had uniformity and a relatively dense distribution. According to the results shown in FIG. 3B and FIG. 3E, the lithium metal on the current collector of Example 2 exhibited a uniform long curled structure, which had uniformity and a relatively dense distribution. According to the results shown in FIG. 3C and FIG. 3F, the lithium metal on the copper foil A of Comparative Example 1 did not exhibit uniformity and had a relatively loose distribution.

### <Measurement of Service Life of Energy Storage Device>

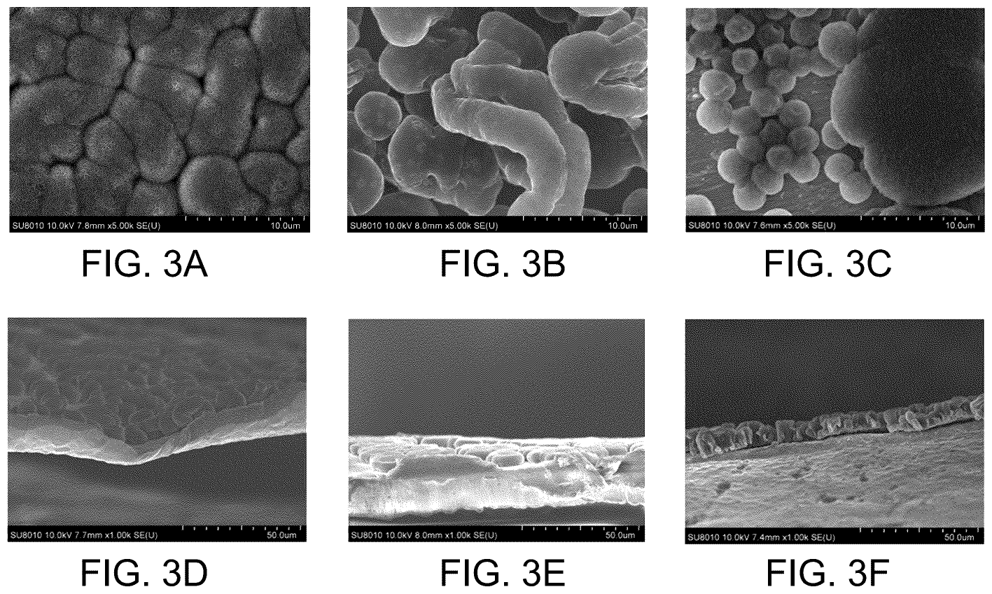

Comparative Example 1 (that is, the copper foil A with no nanographene deposited thereon), Example 1 and Example 2 were each applied in an energy storage device. Next, each energy storage device was charged and discharged multiple times to measure the cycle number (or number of charge and discharge) allowing the energy storage device to maintain high Coulombic efficiency. Further, a comparison in terms of service life was made between each energy storage device, and the results thereof are shown in FIG. 4.

According to the results shown in FIG. 4, the Coulombic efficiency of Comparative Example 1 began to decrease after 160 cycles, the Coulombic efficiency of Example 1 began to decrease after 200 cycles, and the Coulombic efficiency of Example 2 began to decrease after 215 cycles. Accordingly, with reference to the cycle number allowing Comparative Example 1 to maintain high Coulombic efficiency, the service life of Example 1 was increased by about 25% (that is, (200−160)/160), and the service life of Example 2 was increased by about 34% (that is, (215−160)/160).

### Experiment Example 2

First, a current collector of Example 3 was formed. The current collector of Example 3 was prepared in the same way as and under similar conditions to Experimental Example 1, and a difference lies in the following. In a method of manufacturing the current collector of Example 3, ethylene was used as a carbon source, the copper foil B that had been cleaned was used as a base material, a flow rate of argon was 20 sccm, a flow rate of ethylene was 5 sccm, a microwave power was 800 W, and a deposition time was 12 minutes.

The copper foil B with no nanographene deposited thereon was used as a current collector of Comparative Example 2.

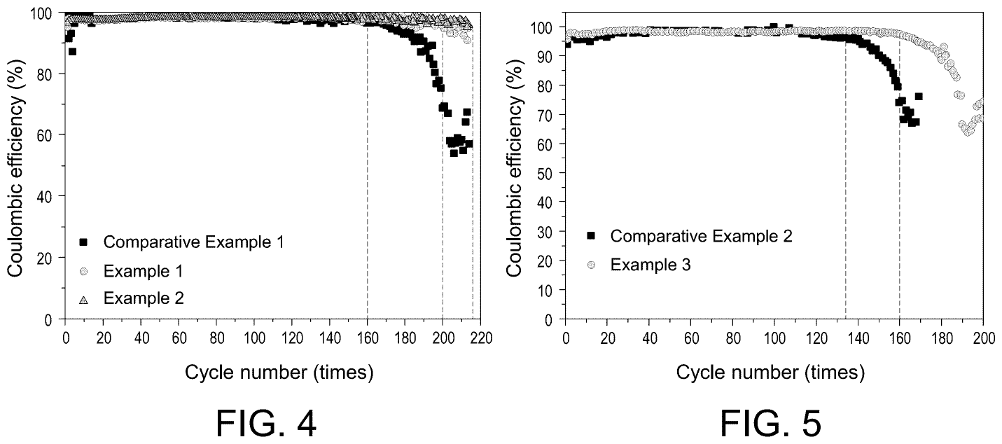

Next, Comparative Example 2 (that is, the copper foil B with no nanographene deposited thereon) and Example 3 were each applied in an energy storage device. Next, each energy storage device was charged and discharged multiple times to measure the cycle number allowing the energy storage device to maintain high Coulombic efficiency. Further, a comparison in terms of service life was made between each energy storage device, and the results thereof are shown in FIG. 5.

According to the results shown in FIG. 5, the Coulombic efficiency of Comparative Example 2 began to decrease after 135 cycles, and the Coulombic efficiency of Example 3 began to decrease after 160 cycles. Accordingly, with reference to the cycle number allowing Comparative Example 2 to maintain high Coulombic efficiency, the service life of Example 3 was increased by about 18% (that is, (160−135)/135).

### Experiment Example 3

First, current collectors of Example 4 to Example 20 were formed. Specifically, the current collectors of Example 4 to Example 9 were prepared in the same way as and under similar conditions to Experimental Example 1, using the copper foil A that had been cleaned with hydrochloric acid as a base material and using acetylene as a carbon source, and differences are described in Table 1. The current collectors of Example 10 to Example 16 were prepared in the same way as and under similar conditions to Experimental Example 1, using the copper foil A that had not been cleaned as a base material and using acetylene as a carbon source, and differences are described in Table 2. The current collectors of Example 17 to Example 18 were prepared in the same way as and under similar conditions to Experimental Example 1, using the copper foil B that had been cleaned with hydrochloric acid as a base material and using acetylene as a carbon source, and differences are described in Table 3. The current collectors of Example 19 to Example 20 were prepared in the same way as and under similar conditions to Experimental Example 1, using the copper foil B that had not been cleaned as a base material and using acetylene as a carbon source, and differences are described in Table 3.

Next, values of the nanographene on the current collectors of Example 4 to Example 20 at the D peak, the G peak and the 2D peak were measured by Raman spectroscopy, so as to calculate a ratio of the value at the D peak to the value at the G peak (D/G value), and calculate a ratio of the value at the 2D peak to the value at the G peak (2D/G value). The results thereof are shown in Table 1 to Table 3. The D/G value may indicate the degree of defectiveness of graphene, and the 2D/G value may indicate the number of layers of graphene. For example, the smaller the D/G value, the fewer defects are present in graphene and the better the quality of graphene; the greater the 2D/G value, the smaller the number of layers of graphene.

TABLE 1

| | Example | Example | Example | Example | Example | Example | Example |
|---|---|---|---|---|---|---|---|
| | 4 | 5 | 6 | 1 | 7 | 8 | 9 |
| Microwave | 1100 | 1100 | 1100 | 1100 | 1100 | 800 | 900 |
| power | | | | | | | |
| Temperature | 450 | 450 | 450 | 450 | 450 | 300 | 25 |
| Argon flow | 30 | 30 | 30 | 30 | 30 | 30 | 30 |
| rate | | | | | | | |
| Hydrogen | 5 | 5 | 5 | 5 | 5 | 5 | 5 |
| flow rate | | | | | | | |
| Acetylene | 10 | 5 | 5 | 2.5 | 1.5 | 2.5 | 5 |
| flow rate | | | | | | | |
| Deposition | 20 | 20 | 6 | 6 | 3 | 6 | 40 |
| time | | | | | | | |
| D/G value | 1.86 | 2.12 | 2.34 | 2.46 | 2.00 | 2.07 | 0.86 |
| 2D/G value | 0.15 | 0.22 | 0.23 | 0.33 | 0.28 | 0.19 | 0.13 |

TABLE 2

| | Example | Example | Example | Example | Example | Example | Example |
|---|---|---|---|---|---|---|---|
| | 10 | 11 | 12 | 13 | 14 | 15 | 16 |
| Microwave | 1100 | 1100 | 1100 | 1100 | 1100 | 800 | 900 |
| power | | | | | | | |
| Temperature | 450 | 450 | 450 | 450 | 450 | 300 | 25 |
| Argon flow | 30 | 30 | 30 | 30 | 30 | 30 | 30 |
| rate | | | | | | | |
| Hydrogen | 5 | 5 | 5 | 5 | 5 | 5 | 5 |
| flow rate | | | | | | | |
| Acetylene | 10 | 5 | 5 | 2.5 | 1.5 | 2.5 | 5 |
| flow rate | | | | | | | |
| Deposition | 20 | 20 | 6 | 6 | 3 | 6 | 40 |
| time | | | | | | | |
| D/G value | 1.90 | 2.35 | 2.40 | 2.41 | 1.92 | 1.91 | 0.82 |
| 2D/G value | 0.16 | 0.24 | 0.25 | 0.30 | 0.29 | 0.21 | 0.15 |

TABLE 3

| | Example 17 | Example 18 | Example 19 | Example 2 | Example 20 |
|---|---|---|---|---|---|
| Microwave | 1100 | 1100 | 1100 | 1100 | 900 |
| power | | | | | |
| Temperature | 450 | 450 | 450 | 450 | 25 |
| Argon flow | 30 | 30 | 30 | 30 | 30 |
| rate | | | | | |
| Hydrogen | 5 | 5 | 5 | 5 | 5 |
| flow rate | | | | | |
| Acetylene | 10 | 5 | 5 | 2.5 | 5 |
| flow rate | | | | | |
| Deposition | 20 | 20 | 6 | 6 | 40 |
| time | | | | | |
| D/G value | 1.69 | 2.18 | 2.40 | 2.42 | 0.85 |
| 2D/G value | 0.13 | 0.22 | 0.24 | 0.28 | 0.13 |

According to Table 1, in Example 9, nanographene was produced at a relatively low temperature (25° C.) and a relatively low microwave power (900 W). As a result, graphene exhibited poor growth and a film thereof had a relatively strange color. On the other hand, in Example 1 and Example 4 to Example 7, nanographene was produced at a relatively high temperature (450° C.) and a relatively high microwave power (1100 W), which could be confirmed through Raman spectroscopy. When the deposition time was reduced to 3 to 6 minutes and the acetylene flow rate was decreased, the thickness of graphene was effectively reduced.

According to Example 1 and Example 6 in Table 1 (or Example 12 and Example 13 in Table 2) (or Example 2 and Example 19 in Table 3), when the acetylene flow rate was increased, the number of layers of graphene was increased (according to the 2D/G value), the quality of graphene was improved and the degree of defectiveness was reduced (according to the D/G value).

According to Example 5 and Example 6 in Table 1 (or Example 11 and Example 12 in Table 2) (or Example 18 and Example 19 in Table 3), when the deposition time was increased, the number of layers of graphene was increased (according to the 2D/G value), the quality of graphene was improved and the degree of defectiveness was reduced (according to the D/G value).

According to Example 1 and Example 8 in Table 1 (or Example 13 and Example 15 in Table 2), when the microwave power or the temperature was reduced, the number of layers of graphene was increased (according to the 2D/G value), the quality of the graphene can be improved and the degree of defectiveness was reduced (according to the D/G value).

### Experiment Example 4

First, current collectors of Example 21 to Example 41 were formed. Specifically, the current collectors of Example 21 to Example 27 were prepared in the same way as and under similar conditions to Experimental Example 1, using the copper foil A that had been cleaned with hydrochloric acid as a base material and using ethylene as a carbon source, and differences are described in Table 4. The current collectors of Example 28 to Example 34 were prepared in the same way as and under similar conditions to Experimental Example 1, using the copper foil A that had not been cleaned as a base material and using ethylene as a carbon source, and differences are described in Table 5. The current collectors of Example 35 to Example 41 were prepared in the same way as and under similar conditions to Experimental Example 1, using the copper foil B that had been cleaned with hydrochloric acid as a base material and using ethylene as a carbon source, and differences are described in Table 6.

Next, values of the nanographene on the current collectors of Example 21 to Example 41 at the D peak, the G peak and the 2D peak were measured by Raman spectroscopy, so as to calculate a ratio of the value at the D peak to the value at the G peak (D/G value), and calculate a ratio of the value at the 2D peak to the value at the G peak (2D/G value). The results thereof are shown in Table 4 to Table 6.

TABLE 4

| | Example | Example | Example | Example | Example | Example | Example |
|---|---|---|---|---|---|---|---|
| | 21 | 22 | 23 | 24 | 25 | 26 | 27 |
| Microwave | 1100 | 1100 | 1100 | 800 | 800 | 800 | 500 |
| power | | | | | | | |
| Temperature | 450 | 450 | 450 | 450 | 450 | 450 | 450 |
| Argon flow | 30 | 30 | 30 | 30 | 30 | 30 | 30 |
| rate | | | | | | | |
| Hydrogen | 5 | 5 | 5 | 5 | 5 | 5 | 5 |
| flow rate | | | | | | | |
| Ethylene | 5 | 2.5 | 1.5 | 5 | 2.5 | 1.5 | 1.5 |
| flow rate | | | | | | | |
| Deposition | 6 | 6 | 6 | 6 | 6 | 6 | 6 |
| time | | | | | | | |
| D/G value | 2.78 | 2.55 | 2.21 | 2.68 | 2.46 | 2.55 | 1.96 |
| 2D/G value | 0.46 | 0.44 | 0.32 | 0.35 | 0.38 | 0.46 | 0.25 |

TABLE 5

| | Example | Example | Example | Example | Example | Example | Example |
|---|---|---|---|---|---|---|---|
| | 28 | 29 | 30 | 31 | 32 | 33 | 34 |
| Microwave | 1100 | 1100 | 1100 | 800 | 800 | 800 | 500 |
| power | | | | | | | |
| Temperature | 450 | 450 | 450 | 450 | 450 | 450 | 450 |
| Argon flow | 30 | 30 | 30 | 30 | 30 | 30 | 30 |
| rate | | | | | | | |
| Hydrogen | 5 | 5 | 5 | 5 | 5 | 5 | 5 |
| flow rate | | | | | | | |
| Ethylene | 5 | 2.5 | 1.5 | 5 | 2.5 | 1.5 | 1.5 |
| flow rate | | | | | | | |
| Deposition | 6 | 6 | 6 | 6 | 6 | 6 | 6 |
| time | | | | | | | |
| D/G value | 2.64 | 2.65 | 2.29 | 2.63 | 2.56 | 2.61 | 2.02 |
| 2D/G value | 0.50 | 0.47 | 0.46 | 0.38 | 0.46 | 0.58 | 0.35 |

TABLE 6

| | Example | Example | Example | Example | Example | Example | Example |
|---|---|---|---|---|---|---|---|
| | 35 | 36 | 37 | 38 | 39 | 40 | 41 |
| Microwave | 1100 | 1100 | 1100 | 800 | 800 | 800 | 500 |
| power | | | | | | | |
| Temperature | 450 | 450 | 450 | 450 | 450 | 450 | 450 |
| Argon flow | 30 | 30 | 30 | 30 | 30 | 30 | 30 |
| rate | | | | | | | |
| Hydrogen | 5 | 5 | 5 | 5 | 5 | 5 | 5 |
| flow rate | | | | | | | |
| Ethylene | 5 | 2.5 | 1.5 | 5 | 2.5 | 1.5 | 1.5 |
| flow rate | | | | | | | |
| Deposition | 6 | 6 | 6 | 6 | 6 | 6 | 6 |
| time | | | | | | | |
| D/G value | 2.61 | 2.40 | 2.03 | 2.59 | 2.69 | 2.28 | 1.83 |
| 2D/G value | 0.44 | 0.28 | 0.27 | 0.34 | 0.35 | 0.33 | 0.22 |

According to Table 4, in Example 27, nanographene was produced at a relatively low microwave power (500 W). As a result, graphene exhibited poor growth and the content thereof was very low. On the other hand, in Example 21 to Example 26, nanographene was produced at a relatively high microwave power (800 W to 1100 W). As a result, graphene exhibited relatively good growth and the content thereof was relatively high, which could be confirmed through Raman spectroscopy.

According to Example 21 in Table 4 (or Example 28 in Table 5) (or Example 35 in Table 6), when both the microwave power and the ethylene flow rate were increased, the number of layers of graphene was reduced (according to the 2D/G value).

According to Example 27 in Table 4 (or Example 34 in Table 5) (or Example 41 in Table 6), when both the microwave power and the ethylene flow rate were decreased, the number of layers of graphene was increased (according to the 2D/G value).

According to Table 4, compared with Example 22 to Example 25 and Example 27, the 2D/G value (2D/G=0.46) was maximum in both Example 21 and Example 26, indicating that Example 21 and Example 26 had a relatively small number of layers of graphene. Since the 2D/G value of Example 21 and Example 26 was between 0.4 and 0.6, the number of layers of graphene in Example 21 and Example 26 was about 4 to 5.

According to Table 5, compared with Example 29 to Example 32 and Example 34, the 2D/G value (2D/G=0.50 in Example 28 and 2D/G=0.58 in Example 33) was maximum in both Example 28 and Example 33, indicating that Example 28 and Example 33 had a relatively small number of layers of graphene. Since the 2D/G value of Example 28 and Example 33 was between 0.4 and 0.6, the number of layers of graphene in Example 28 and Example 33 was about 4 to 5.

According to Table 6, compared with Example 36 to Example 41, the 2D/G value (2D/G=0.44) was maximum in Example 35, indicating that Example 35 had a relatively small number of layers of graphene. Since the 2D/G value of Example 35 was between 0.4 and 0.6, the number of layers of graphene in Example 35 was about 4 to 5. Since the 2D/G value of Example 37 to Example 39 was less than 0.4, the number of layers of graphene in Example 37 to Example 39 was about 5 to 10.

To sum up, in the energy storage device and the method of manufacturing a current collector of the energy storage device according to an exemplary embodiment, by disposing a modified layer that contains nanographene on a substrate, formation of lithium dendrites on the current collector during reduction of lithium ions (or during charging) can be prevented, and the safety and service life of the energy storage device can be improved. Compared with a conventional method of manufacturing a current collector having a modified layer which requires multiple steps (for example, coating, deposition, and annealing), long time (for example, 2 hours or more), and/or high temperature (for example, 1000° C. or higher), in the method of the present embodiment, the current collector including the modified layer that contains nanographene can be manufactured by a single step (microwave plasma chemical vapor deposition process) within a relatively short time (less than 30 minutes) at a relatively low temperature (300° C. to 450° C.). The manufacturing process is simplified and shortened.

It will be apparent to those skilled in the art that various modifications and variations can be made to the disclosed embodiments. It is intended that the specification and examples be considered as exemplars only, with a true scope of the disclosure being indicated by the following claims and their equivalents.

What is claimed is:

1. A method of manufacturing a current collector of an energy storage device, comprising:
providing a substrate; and
forming a modified layer on the substrate using a microwave plasma chemical vapor deposition process, the modified layer comprising nanographene and having a thickness of 1 nm to 500 nm, wherein,
in the microwave plasma chemical vapor deposition process, a microwave frequency is 300 MHz to 300 GHz, a microwave power is 500 W to 75000 W, a temperature is 25° C. to 600° C., and a deposition time is less than 30 minutes, and
the microwave plasma chemical vapor deposition process comprises:
passing in inert gas or stable gas;
passing in hydrocarbon gas and hydrogen;
applying microwaves to generate plasma;
ionizing the hydrocarbon gas and the hydrogen using the plasma; and
depositing the nanographene on the substrate.

2. The method of manufacturing a current collector of an energy storage device according to claim 1, wherein
a material of the substrate comprises a metal material, a conductive material, or a conductive polymer material.

3. The method of manufacturing a current collector of an energy storage device according to claim 1, wherein
the microwave plasma chemical vapor deposition process is an electron cyclotron resonance chemical vapor deposition process, a multi-source electron cyclotron resonance chemical vapor deposition process, a microwave plasma torch chemical vapor deposition process, or a focused microwave plasma chemical vapor deposition process.

4. The method of manufacturing a current collector of an energy storage device according to claim 1, wherein
the nanographene comprises 1 to 10 layers.

5. The method of manufacturing a current collector of an energy storage device according to claim 1, wherein
the nanographene is a graphene nanowall or horizontal graphene.

6. The method of manufacturing a current collector of an energy storage device according to claim 1, wherein
the stable gas comprises nitrogen.

7. The method of manufacturing a current collector of an energy storage device according to claim 1, wherein
the hydrocarbon gas comprises alkane gas, alkene gas, or acetylene gas.

8. The method of manufacturing a current collector of an energy storage device according to claim 1, wherein
a ratio between the hydrocarbon gas and the hydrogen is 1:10 to 10:1.

9. The method of manufacturing a current collector of an energy storage device according to claim 1, wherein
the energy storage device is an anode-free lithium metal battery, and the current collector is an anode current collector.

10. The method of manufacturing a current collector of an energy storage device according to claim 1, wherein the microwave plasma chemical vapor deposition process further comprises:
doping with heteroatoms, wherein the heteroatoms comprise nitrogen, sulfur, or silicon.

11. An energy storage device, comprising:
a cathode;
a separator, disposed on the cathode;
a current collector manufactured by the method of manufacturing a current collector of an energy storage device according to claim 1, disposed on the separator; and
an electrolytic solution, disposed between the cathode and the current collector.

12. The energy storage device according to claim 11, wherein
a material of the cathode comprises lithium iron phosphate, lithium nickel manganese cobalt oxide, lithium cobalt oxide, lithium nickel cobalt aluminum oxide, or lithium foil.

13. The energy storage device according to claim 11, wherein
a material of the separator comprises polypropylene or polyethylene.

14. The energy storage device according to claim 11, wherein
an electrolyte in the electrolytic solution comprises lithium carbonate, lithium hexafluorophosphate, lithium tetrafluoroborate, lithium bis(trifluoromethanesulfonyl)imide, lithium bis(fluorosulfonyl)imide, or lithium nitrate.

15. The energy storage device according to claim 11, wherein
a solvent in the electrolytic solution comprises ethylene carbonate, dimethyl carbonate, ethyl methyl carbonate, dimethoxyethane, or 1,3-dioxolane.

16. The energy storage device according to claim 11, wherein
the energy storage device is an anode-free lithium metal battery, and the current collector is an anode current collector.
